(19) United States
(12) Patent Application Publication
(10) Pub. No.: US 2024/0290843 A1
(43) Pub. Date: Aug. 29, 2024

(54) SEMICONDUCTOR ELEMENT AND PRODUCTION METHOD FOR SEMICONDUCTOR ELEMENT

(71) Applicants: AIR WATER INC., Chuo-ku, Osaka-shi, Osaka (JP); UNIVERSITY PUBLIC CORPORATION OSAKA, Abeno-ku, Osaka-shi, Osaka (JP)

(72) Inventors: Keisuke KAWAMURA, Matsumoto-shi, Nagano (JP); Koichi KITAHARA, Matsumoto-shi, Nagano (JP); Jianbo LIANG, Osaka-shi, Osaka (JP); Naoteru SHIGEKAWA, Osaka-shi, Osaka (JP)

(21) Appl. No.: 18/572,949

(22) PCT Filed: Jun. 22, 2022
(86) PCT No.: PCT/JP2022/024816

§ 371 Date: Dec. 21, 2023

(30) Foreign Application Priority Data
Jun. 25, 2021 (JP) 2021-105412

(51) Int. Cl. H01L 29/16; H01L 29/04; H01L 29/26; H01L 29/45; H01L 29/47; H01L 29/66

(52) U.S. Cl. CPC H01L 29/1608; H01L 29/045; H01L 29/263; H01L 29/45; H01L 29/47; H01L 29/66068

(57) ABSTRACT

A semiconductor element and a method for manufacturing a semiconductor element improving heat dissipation are provided. A semiconductor element includes a Ga₂O₃(gallium oxide) substrate, a single-crystal SiC layer formed at one principal surface side of the Ga₂O₃ substrate, and a Schottky electrode formed at the one principal surface side of the Ga₂O₃ substrate and controls current flowing inside the Ga₂O₃ substrate.

### BACKGROUND OF THE INVENTION

### Technological Field

The present invention relates to a semiconductor element and a method for manufacturing a semiconductor element. More specifically, the present invention relates to a semiconductor element and a method for manufacturing the semiconductor element with a Ga₂O₃ (gallium oxide) layer.

### Description of the Related Art

Ga₂O₃ has a larger band gap than SiC (silicon carbide) and GaN (gallium nitride) and has recently attracted attention as a new wide-gap semiconductor material. Baliga performance index is known as an index indicating a basic performance of a power element. The Baliga performance index of Ga₂O₃ is several times larger than each of the Baliga performance index of SiC and the Baliga performance index of GaN. For this reason, Ga₂O₃ is expected to be applied to energy-saving power semiconductor elements.

On the other hand, Ga₂O₃ has a thermal conductivity of approximately 0.1 W/cm*K. The thermal conductivity of Ga₂O₃ is significantly lower than that of SiC (approximately 4.9 W/cm*K) and that of GaN (approximately 2 W/cm*K). For this reason, when Ga₂O₃ is applied to a power semiconductor element, there is a concern that the heat dissipation of the power semiconductor element will deteriorate. The reduction in heat dissipation of a power semiconductor element causes a reduction in device performance and reliability due to heat generation of Ga₂O₃ itself during the operation.

In Patent Document 1 below, a conventional power semiconductor element including Ga₂O₃ is disclosed. According to the Patent Document 1 below, a semiconductor element is disclosed, which includes a Ga₂O₃ based substrate, a single-crystal Ga₂O₃ based layer, an anode electrode, a polycrystal SiC substrate, and a cathode electrode. The single-crystal Ga₂O₃ based layer is formed on the surface of the Ga₂O₃ based substrate. The anode electrode is in Schottky contact with the single-crystal Ga₂O₃ based layer. The polycrystal SiC substrate is joined to the reverse side of the Ga₂O₃ based substrate. The cathode electrode is in ohmic contact with the polycrystal SiC substrate.

### PRIOR ART DOCUMENT

### Document(s) Related to Patents

[Patent Document 1] Japanese published unexamined application No. 2019-14639

### SUMMARY OF THE INVENTION

In the power semiconductor element of Patent Document 1, heat generated at a Schottky joint interface in the single-crystal Ga₂O₃ based layer travels through each of the Ga₂O₃ based substrate and the polycrystal SiC substrate in the thickness direction (a direction perpendicular to the surface of the Ga₂O₃ based substrate) and is emitted to the outside from the reverse side of the polycrystal SiC substrate. In the power semiconductor element of Patent Document 1, since the path for heat to be released to the outside is long, there is still a problem of poor heat dissipation.

Here, in order to improve heat dissipation by shortening a path through which heat is released to the outside, it is also possible to make the Ga₂O₃ based substrate and the polycrystal SiC substrate thinner. However, the Ga₂O₃ based substrate and the polycrystal SiC substrate are hard, so a method such as chemical polishing cannot be used because the polishing speed is slow. When using a method such as mechanical polishing that has a high polishing speed, it is difficult to reduce the thickness of the Ga₂O₃ based substrate and the polycrystal SiC substrate to a uniform thickness. For this reason, it was difficult to improve heat dissipation by making the Ga₂O₃ based substrate and the polycrystal SiC substrate thinner.

The present invention is to solve the above problems, the purpose is to provide a semiconductor element and a method for manufacturing a semiconductor element that can improve heat dissipation.

According to one aspect, a semiconductor element comprises: a gallium oxide layer; a single-crystal silicon carbide layer formed at one principal surface side of the gallium oxide layer; and a first electrode formed at the one principal surface side of the gallium oxide layer and controls current flowing inside the gallium oxide layer.

Preferably, the silicon carbide layer has a 3C type crystal structure, a plane orientation of a principal surface of the silicon carbide layer at the gallium oxide layer side is (111), (100), or (110), an off angle of the principal surface of the silicon carbide layer at the gallium oxide layer side is between 0° and 10°, and the silicon carbide layer satisfies at least one of the conditions of a half width of a X-ray rocking curve of the surface orientation of the principal surface of the silicon carbide layer at the gallium oxide layer side is greater than 0 and equal to or less than 2000 arcsec, and a full width at half maximum of the misorientation distribution of the principal surface of the silicon carbide layer at the gallium oxide layer side determined by an electron beam backscatter diffraction method is greater than 0 and equal to or less than 2000 arcsec.

The silicon carbide layer has a crystal structure of a hexagonal crystal, the surface orientation of the principal surface of the silicon carbide layer at the gallium oxide layer side is (0001), an off angle of the principal surface of the silicon carbide layer at the gallium oxide layer side is between 0° and 10°, and the silicon carbide layer satisfies at least one of the conditions of a half width of a X-ray rocking curve of the surface orientation of the principal surface of the silicon carbide layer at the gallium oxide layer side is greater than 0 and equal to or less than 2000 arcsec, and a full width at half maximum of the misorientation distribution of the principal surface of the silicon carbide layer at the gallium oxide layer side determined by an electron beam backscatter diffraction method is greater than 0 and equal to or less than 2000 arcsec.

Preferably, the semiconductor element according to claim 1 further comprises: a conjugation layer formed at a boundary face between the gallium oxide layer and the silicon carbide layer.

Preferably, the conjugation layer includes a first amorphous layer consisting of gallium oxide formed on the one principal surface of the gallium oxide layer, and a second amorphous layer consisting of silicon carbide formed between the first amorphous layer and the silicon carbide layer.

Preferably, the conjugation layer includes silicon oxide.

Preferably, the gallium oxide layer includes a first gallium oxide layer, and a second gallium oxide layer formed on one principal surface of the first gallium oxide layer and having a lower conductivity than the first gallium oxide layer.

Preferably, the conjugation layer is formed in a first region of one principal surface of the second gallium oxide layer, and the first electrode is formed in a second region of the one principal surface of the second gallium oxide layer, which is different from the first region.

Preferably, the second gallium oxide layer is formed in a third region of the one principal surface of the first gallium oxide layer, the conjugation layer is formed in a fourth region of the one principal surface of the first gallium oxide layer, which is different from the third region, and the first electrode is formed on one principal surface of the second gallium oxide layer.

Preferably, a side surface, which is a surface between two principal surfaces of the second gallium oxide layer, contacts the silicon carbide layer.

Preferably, the first electrode is in Schottky contact with the gallium oxide layer, and the semiconductor element further comprising: a second electrode in ohmic contact with other principal surface of the gallium oxide layer.

According to another aspect, a method for manufacturing a semiconductor element comprises: a step of joining one principal surface of a gallium oxide layer and a single-crystal silicon carbide layer; and a step of forming a first electrode at the one principal surface side of the gallium oxide layer for controlling current flowing in the gallium oxide layer.

### Effect of the Invention

According to the present invention, it is possible to provide a semiconductor element and a method for manufacturing a semiconductor element that can improve heat dissipation.

### BRIEF DESCRIPTION OF THE DRAWINGS

FIG. 1 is a cross-sectional view showing the configuration of semiconductor element SD1 in the first embodiment of the present invention.

FIG. 2 shows a cross-sectional view indicating the first step of the method for manufacturing semiconductor element SD1 in the first embodiment of the present invention.

FIG. 3 shows a cross-sectional view indicating the second step of the method for manufacturing semiconductor element SD1 in the first embodiment of the present invention.

FIG. 4 shows a cross-sectional view indicating the third step of the method for manufacturing semiconductor element SD1 when using a surface activated bonding method in the first embodiment of the present invention.

FIG. 5 shows a cross-sectional view indicating the fourth step of the method for manufacturing semiconductor element SD1 when using a surface activated bonding method in the first embodiment of the present invention.

FIG. 6 is an enlarged view of the main part of FIG. 5.

FIG. 7 shows a cross-sectional view indicating the third step of the method for manufacturing semiconductor element SD1 in the first embodiment of the present invention, when a hydrophilic bonding method is used.

FIG. 8 shows a cross-sectional view indicating the fourth step of the method for manufacturing semiconductor element SD1 in the first embodiment of the present invention, when a hydrophilic bonding method is used.

FIG. 9 is an enlarged view of the main part of FIG. 8.

FIG. 10 shows a cross-sectional view indicating the fifth step of the method for manufacturing semiconductor element SD1 in the first embodiment of the present invention.

FIG. 11 shows a cross-sectional view indicating the sixth step of the method for manufacturing semiconductor element SD1 in the first embodiment of the present invention.

FIG. 12 shows a cross-sectional view indicating the seventh step of the method for manufacturing semiconductor element SD1 in the first embodiment of the present invention.

FIG. 13 is a cross-sectional view showing the heat dissipation path of semiconductor element SD1 in the first embodiment of the present invention.

FIG. 14 is a cross-sectional view showing the first step of modification of the method for manufacturing of the first embodiment of the present invention.

FIG. 15 is a cross-sectional view showing the second step of the modification of the method for manufacturing of the first embodiment of the present invention.

FIG. 16 is a cross-sectional view showing the third step of the modification of the method for manufacturing of the first embodiment of the present invention.

FIG. 17 is a cross-sectional view showing the configuration of semiconductor element SD2 in the second embodiment of the present invention.

FIG. 18 is a cross-sectional view showing the first step of the method for manufacturing semiconductor element SD2 in the second embodiment of the present invention.

FIG. 19 is a cross-sectional view showing the second step of the method for manufacturing semiconductor element SD2 in the second embodiment of the present invention.

FIG. 20 is a cross-sectional view showing the third step of the method for manufacturing semiconductor element SD2 in the second embodiment of the present invention.

FIG. 21 is a cross-sectional view showing the fourth step of the method for manufacturing semiconductor element SD2 in the second embodiment of the present invention.

FIG. 22 is a cross-sectional view showing the fifth step of the method for manufacturing semiconductor element SD2 in the second embodiment of the present invention.

FIG. 23 is a cross-sectional view showing the sixth step of the method for manufacturing semiconductor element SD2 in the second embodiment of the present invention.

FIG. 24 is a cross-sectional view showing the first step of a modification of the method for manufacturing semiconductor element SD2 in the second embodiment of the present invention.

FIG. 25 is a cross-sectional view showing the second step of the modification of the method for manufacturing semiconductor element SD2 in the second embodiment of the present invention.

FIG. 26 is a cross-sectional view showing the third step of the modification of the method for manufacturing semiconductor element SD2 in the second embodiment of the present invention.

FIG. 27 is a cross-sectional view showing the heat dissipation path of semiconductor element SD2 in the second embodiment of the present invention.

FIG. 28 is a cross-sectional view showing the configuration of semiconductor element SD3 in the third embodiment of the present invention.

FIG. 29 is a cross-sectional view showing the configuration of semiconductor element SD101 which becomes Sample 3 (a comparative example) in the first Example of the present invention.

FIG. 30 is a diagram showing the relationship between the thermal resistance value and the thickness of the drift layer of each of Samples 1 to 3 in the first Examples of the present invention.

FIG. 31 is a diagram showing the relationship between the surface temperature and the thickness of the SiC layer of Sample 4 in the second Example of the present invention.

FIG. 32 is a diagram showing the configuration of Sample 5 and each measurement value of Sample 5 in the third Example of the present invention.

### DETAILED DESCRIPTION OF EMBODIMENTS

Hereinafter, embodiments of the present invention will be described with reference to the drawings. In the following description, the expression “formed on a principal surface” means formed in contact with the principal surface. The expression “formed at a principal surface side” means both being formed in contact with the principal surface, and being formed without contact with the principal surface (at a distance from the principal surface).

### First Embodiment

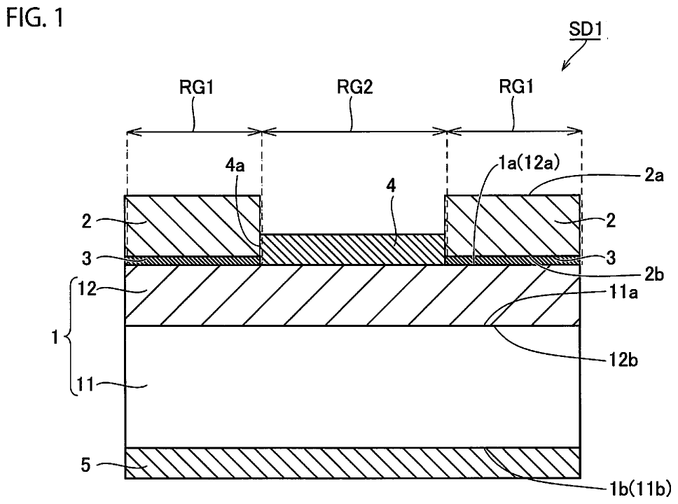

FIG. 1 is a cross-sectional view showing the configuration of semiconductor element SD1 in the first embodiment of the present invention. Note that in the drawing, conjugation layer 3 is drawn thicker than its actual thickness.

Referring to FIG. 1, semiconductor element SD1 (an example of a semiconductor element) in the first embodiment is an SBD (Schottky Barrier Diode). Semiconductor element SD1 consists of Ga₂O₃ substrate 1 (an example of a gallium oxide layer), SiC layer 2 (an example of a single-crystal silicon carbide layer), conjugation layer 3 (an example of a conjugation layer), Schottky electrode 4 (an example of a first electrode). and an ohmic electrode 5 (an example of a second electrode). Ga₂O₃ substrate 1 contains two principal surfaces 1a and 1b. Principal surface 1a of Ga₂O₃ substrate 1 faces upward in FIG. 1. Principal surface 1b of Ga₂O₃ substrate 1 faces downward in FIG. 1. It is preferable that the thickness of the Ga₂O₃ substrate 1 (length in the vertical direction in FIG. 1) is set according to the withstand voltage required for the semiconductor element SD1. Ga₂O₃ substrate 1 includes foundation substrate 11 (an example of a first gallium oxide layer) and drift layer 12 (an example of a second gallium oxide layer).

Foundation substrate 11 contains two principal surfaces 11a and 11b. The principal surface 11a of foundation substrate 11 faces upward in FIG. 1. Principal surface 11b of foundation substrate 11 faces downward in FIG. 1 and constitutes principal surface 1b of Ga₂O₃ substrate 1. From the viewpoint of reducing parasitic resistance of the vertical SBD, foundation substrate 11 preferably has an impurity concentration as high as possible, and preferably has an impurity concentration of 10¹⁸ pieces/cm³ or more and 10²⁰ pieces/cm³ or less.

Drift layer 12 is formed on principal surface 11a of foundation substrate 11. Drift layer 12 includes two principal surfaces 12a and 12b. Principal surface 12a of drift layer 12 faces upward in FIG. 1 and constitutes principal surface 1a of Ga₂O₃ substrate 1. Principal surface 12b of drift layer 12 faces downward in FIG. 1 and is in contact with principal surface 11a of foundation substrate 11. The electrical conductivity of drift layer 12 is lower than that of foundation substrate 11. To adjust the conductivity, each of the foundation substrate 11 and the drift layer 12 may contains an impurity such as Si (silicon), Sn (tin), or Ge (germanium), and may have an n-type conductivity.

Drift layer 12 preferably has a thickness of 1 micrometer or more and 50 micrometers or less. Drift layer 12 preferably has an impurity concentration of 10¹⁴ or more and 10¹⁷ or less/cm³. The thickness and impurity concentration of drift layer 12 are set according to the withstand voltage required for the SBD.

Since the Ga₂O₃ substrate 1 includes the foundation substrate 11 and the drift layer 12, the high conductivity of the foundation substrate 11 can ensure the conductivity of the semiconductor element SD1. In addition, the high insulation properties of the drift layer 12 ensure high breakdown voltage within the semiconductor element SD1.

SiC layer 2 is formed at the principal surface 1a side of Ga₂O₃ substrate 1. SiC layer 2 is a single-crystal and has a crystal structure such as 3C type, hexagonal crystal, or the like. SiC layer 2 contains two principal surfaces 2a and 2b. Principal surface 2a of SiC layer 2 faces upward in FIG. 1, and principal surface 2b of SiC layer 2 faces downward in FIG. 1. SiC layer 2 has a thickness of, for example, 1 micrometer to 4 micrometers. In the first embodiment, principal surface 1a of Ga₂O₃ substrate 1 (principal surface 12a of drift layer 12) and principal surface 2b of SiC layer 2 are joined to each other. SiC layer 2 of a single-crystal has high thermal conductivity. For this reason, SiC layer 2 plays a role of releasing the heat generated in semiconductor element SD1 to the outside.

Conjugation layer 3 is formed on the boundary face between Ga₂O₃ substrate 1 and SiC layer 2. Conjugation layer 3 is formed in region RG1 of principal surface 12a of drift layer 12, and is in contact with principal surface 2b of SiC layer 2.

Schottky electrode 4 is formed in region RG2 of principal surface 12a of drift layer 12. Region RG2 is a different region from region RG1. In the first embodiment, the region RG1 and the region RG2 are adjacent to each other, and the side surface 4a of the Schottky electrode 4 is in contact with the SiC layer 2. Schottky electrode 4 is in Schottky contact with principal surface 1a of Ga₂O₃ substrate 1 (principal surface 12a of drift layer 12). Schottky electrode 4 is made of, for example, Pt (platinum)/Ti (titanium)/Au (gold) electrode.

Ohmic electrode 5 is formed on the principal surface 1b of the Ga₂O₃ substrate 1. The ohmic electrode 5 is in ohmic contact with the principal surface 1b of the Ga₂O₃ substrate 1 (principal surface 11b of the foundation substrate 11). The ohmic electrode 5 is made of, for example, a Ti/Au electrode.

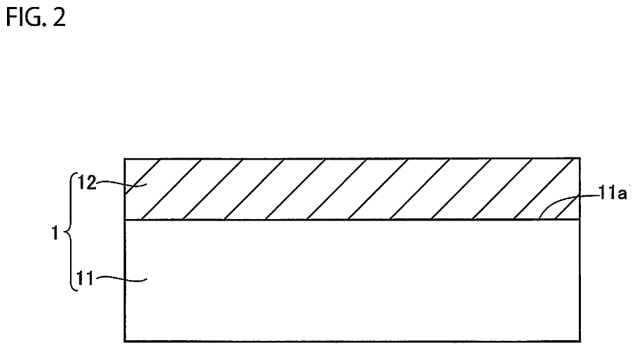

Next, the method for manufacturing semiconductor element SD1 in the first embodiment will be explained with FIGS. 2 to 12.

Referring to FIG. 2, foundation substrate 11 is prepared. The plane orientation of the principal surface 11a of the foundation substrate 11 is arbitrary, and is preferably a (010) plane or the like. In order to adjust the conductivity, the foundation substrate 11 may contain an impurity such as Mg (magnesium) or N (nitrogen). Foundation substrate 11 may be amorphous. At least when bonding Ga₂O₃ substrate 1 and SiC layer 2, foundation substrate 11 needs to play a role as a supporting member. For this reason, at the stage of FIG. 2, the foundation substrate 11 preferably has a thickness of 100 micrometers or more and 1000 micrometers or less.

Next, a drift layer 12 is formed on the principal surface 11a of the foundation substrate 11 using, for example, the MBE (Molecular Beam Epitaxy) method, the MOCVD (Metal Organic Chemical Vapor Deposition) method, or the HVPE (Hydride Vapor Phase Epitaxy) method. Drift layer 12 epitaxially grows on principal surface 11a of foundation substrate 11. Hence, Ga₂O₃ substrate 1 is obtained. The crystal structure of Ga₂O₃ constituting each of the foundation substrate 11 and the drift layer 12 is arbitrary, and is preferably μ-type. μ-type Ga₂O₃ is more stable than other crystal structure Ga₂O₃ such as α-type Ga₂O₃.

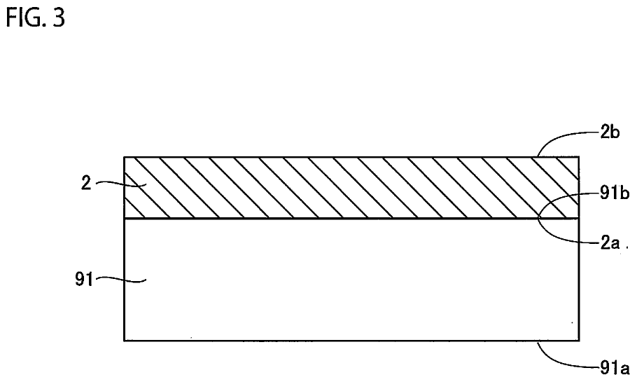

Referring to FIG. 3, next, Si substrate 91 is prepared separately from Ga₂O₃ substrate 1. The Si substrate 91 is made of p-type Si, for example. Si substrate 91 includes two principal surfaces 91a and 91b. The principal surface 91a of the Si substrate 91 faces downward in FIG. 3, and the principal surface 91b of the Si substrate 91 faces upward in FIG. 3. The plane orientation of the principal surface 91b of the Si substrate 91 is, for example, a (111) plane. The Si substrate 91 may have an n-type conductivity or may be semi-insulating. The plane orientation of the principal surface 91b of the Si substrate 91 may be a (100) plane, a (110) plane, or the like. The Si substrate 91 has a diameter of 6 inches and a thickness of 1000 micrometers, for example.

Next, a single-crystal SiC layer 2 is formed on the principal surface 91b of the Si substrate 91. SiC layer 2 includes two principal surfaces 2a and 2b. Principal surface 2a of SiC layer 2 faces downward in FIG. 3, and principal surface 2b of SiC layer 2 faces upward in FIG. 3. SiC layer 2 may be formed by making SiC homo epitaxial growth, using the MBE method, the CVD (Chemical Vapor Deposition) method, the LPE (Liquid Phase Epitaxy) method, etc. on a foundation layer made of SiC obtained by carbonizing principal surface 91b of Si substrate 91. SiC layer 2 may be formed only by carbonizing principal surface 91b of Si substrate 91. Further, the SiC layer 2 may be formed by hetero epitaxial growth on the principal surface 91b of the Si substrate 91 (or with a buffer layer in between). Note that SiC layer 2 may have n-type or p-type conductivity, or may be semi-insulating. Preferably, SiC layer 2 is not intentionally doped with impurity.

When SiC layer 2 is formed on principal surface 91b of Si substrate 91 by carbonizing, homo epitaxial growth, or hetero epitaxial growth, SiC layer 2 has 3C type crystal structure. When SiC layer 2 has 3C type crystal structure, the plane orientation of the principal surface (the principal surface of Ga₂O₃ substrate 1 side) 2b of SiC layer 2 is preferably (111), (100), or (110). The off angle of principal surface 2b of SiC layer 2 is preferably 0 degree or more and 10 degrees or less. Preferably, SiC layer 2 satisfies at least one of the two conditions (a) and (b), the conditions are (a) The half width of the X-ray rocking curve of the plane orientation of principal surface 2b of SiC layer 2 is greater than 0 and equal to or less than 2000 arcsec, and (b) The full width at half maximum of the misorientation distribution of principal surface 2b of SiC layer 2 by electron beam backscatter diffraction method is greater than 0 and equal to or less than 2000 arcsec. Hence, principal surface 2b of SiC layer 2 is a suitable surface for bonding.

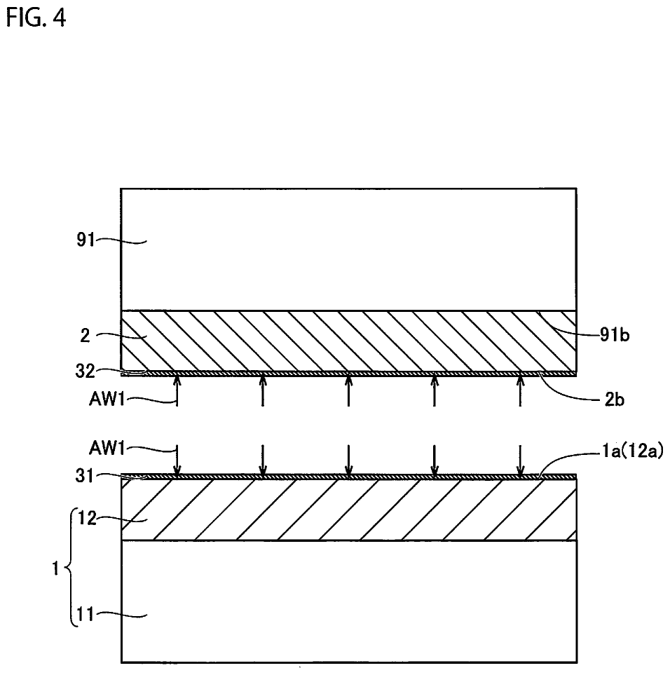

Referring to FIG. 4, next, Si substrate 91 and SiC layer 2 are inverted so that principal surface 91b of Si substrate 91 and principal surface 2b of SiC layer 2 face downward in FIG. 4. The Ga₂O₃ substrate 1 obtained in the step shown in FIG. 2 is brought into a state with the principal surface 1a of the Ga₂O₃ substrate 1 facing upward in FIG. 4. In this state, principal surface 1a of Ga₂O₃ substrate 1 (principal surface 12a of drift layer 12) and principal surface 2b of SiC layer 2 are bonded. In order to ensure contact with the principal surface 1a of the Ga₂O₃ substrate 1, the arithmetic mean roughness Ra of the principal surface 2b of the SiC layer 2 is preferably greater than 0 and less than or equal to 1 nanometer. The arithmetic mean roughness Ra of principal surface 2b of SiC layer 2 is preferably greater than 0 and 0.5 nanometer or less. When the size of the Si substrate 91 is 4 inches or more, the warpage of the principal surface 2b of the SiC layer 2 is preferably greater than 0 and less than or equal to 50 micrometers.

Any method can be used to bond the principal surface 1a of the Ga₂O₃ substrate 1 and the principal surface 2b of the SiC layer 2, and it is preferable to use a surface activated bonding method. When using a surface activated bonding method, in a reduced pressure of 1*10⁻⁵ Pa or less, preferably 1*10⁻⁶ Pa or less, and in an ambient temperature (as an example, a temperature of 10 degrees Celsius or more and 30 degrees Celsius or less) atmosphere, energy particles are irradiated to each of principal surface 1a of Ga₂O₃ substrate 1 and principal surface 2b of SiC layer 2 as shown by arrows AW1. Hence, adsorbed substances such as gas, water, organic matter, or oxygen are removed from each of principal surface 1a of Ga₂O₃ substrate 1 and principal surface 2b of SiC layer 2. The energetic particles are composed of, for example, ions, neutral atoms such as Ar (argon), Kr (krypton), or Ne (neon), or cluster ions. Preferably, the energetic particles are made of Ar.

Here, when principal surface 1a of Ga₂O₃ substrate 1 and principal surface 2b of SiC layer 2 are irradiated with energy particles, for example, amorphous layers 31 and 32 (an example of first and second amorphous layers) with a thickness greater than 0 and less than or equal to 5 nanometers appear on each of principal surface 1a of Ga₂O₃ substrate 1 and principal surface 2b of SiC layer 2, respectively. The amorphous layer 31 is formed by Ga₂O₃ existing on the principal surface 1a of the Ga₂O₃ substrate 1 becoming amorphous due to collisions with energy particles. The amorphous layer 32 is amorphous SiC present on principal surface 2a of SiC layer 2 due to collision with energy particles.

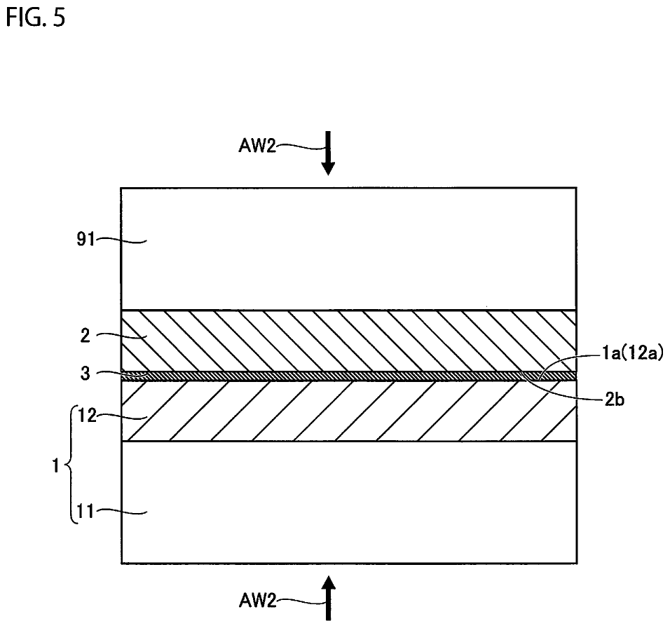

Referring to FIG. 5, next, amorphous layer 31 and amorphous layer 32 are brought into contact with each other as shown by arrows AW2. Hence, principal surface 1a of Ga₂O₃ substrate 1 and principal surface 2b of SiC layer 2 are joined, and conjugation layer 3 appears.

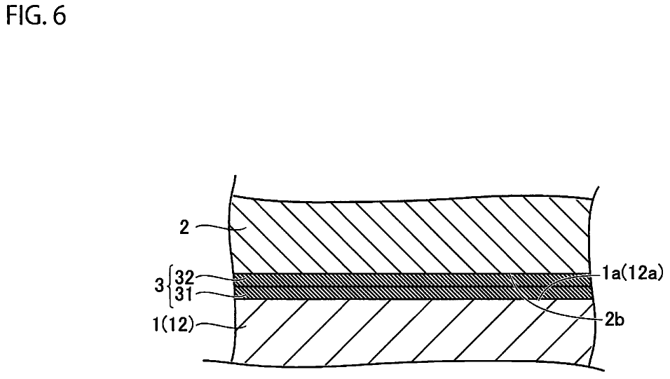

Referring to FIG. 6, conjugation layer 3 is the trace of the junction between Ga₂O₃ substrate 1 and SiC layer 2. If Ga₂O₃ substrate 1 and SiC layer 2 are not joined, conjugation layer 3 will not appear. The components of conjugation layer 3 depend on the joining method. When using the surface activated bonding method, conjugation layer 3 includes amorphous layer 31 and amorphous layer 32. Amorphous layer 31 is formed on principal surface 1a of Ga₂O₃ substrate 1. Amorphous layer 32 is formed between amorphous layer 31 and principal surface 2a of SiC layer 2. Amorphous layers 31 and 32 can be observed by a TEM (Transmission electron microscopy) or the like.

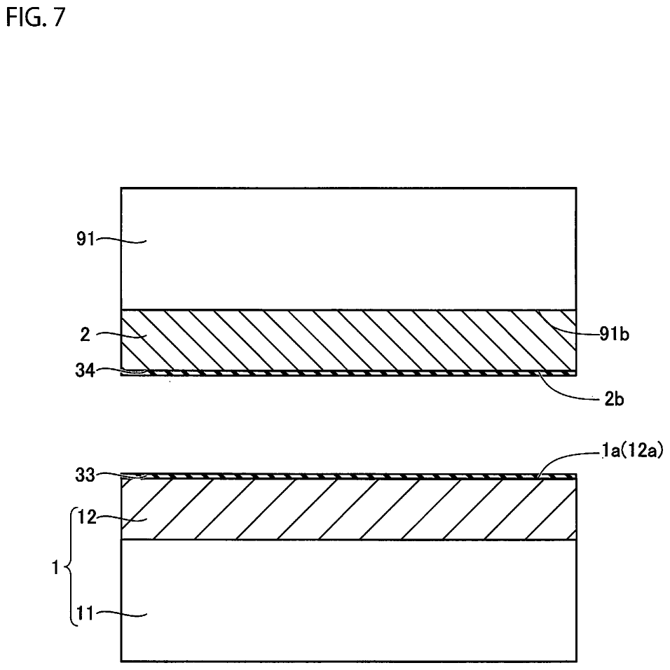

Referring to FIG. 7, a hydrophilic bonding method may be used instead of the surface activated bonding method as a method of joining principal surface 1a of Ga₂O₃ substrate 1 and principal surface 2b of SiC layer 2. The hydrophilic bonding method is also called a Fusion Bonding or a Silicon Direct Bonding (SDB). When using the hydrophilic bonding method, SiO₂ layer 33 is formed on principal surface 1a of Ga₂O₃ substrate 1 using a CVD method or the like. Next, SiO₂ layer 34 is formed on principal surface 2b of SiC layer 2. The SiO₂ layer 34 can be formed by forming SiO₂ layer 34 on the principal surface 2b of SiC layer 2 using a CVD method or the like, forming a Si layer on the principal surface 2b of the SiC layer 2 and thermally oxidizing the Si layer, or thermally oxidizing principal surface 2b of SiC layer 2, or the like. Next, each of the SiO₂ layer 33 and the SiO₂ layer 34 is subjected to a hydrophilic treatment.

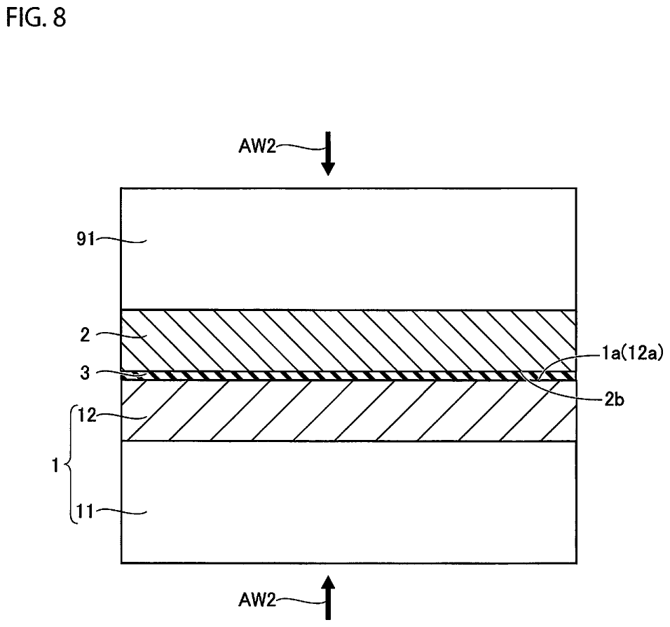

Referring to FIG. 8, next, as shown by arrows AW2, SiO₂ layer 33 and SiO₂ layer 34 are brought into contact with each other. Hence, principal surface 1a of Ga₂O₃ substrate 1 and principal surface 2b of SiC layer 2 are joined, and conjugation layer 3 appears.

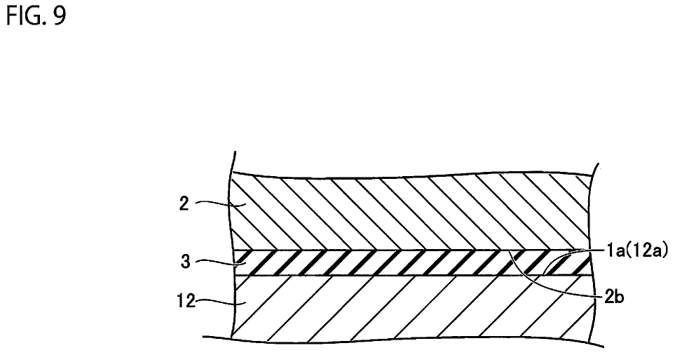

Referring to FIG. 9, when the above hydrophilic bonding method is used, conjugation layer 3 in which SiO₂ layers 33 and 34 are integrated is obtained after bonding. Conjugation layer 3 contains SiO₂.

The thermal conductivity of the SiO₂ layer is relatively low. Conjugation layer 3, when using a surface activated bonding method, does not contain a SiO₂ layer. From the viewpoint of ensuring high thermal conductivity, it is preferable to use a surface activated bonding method.

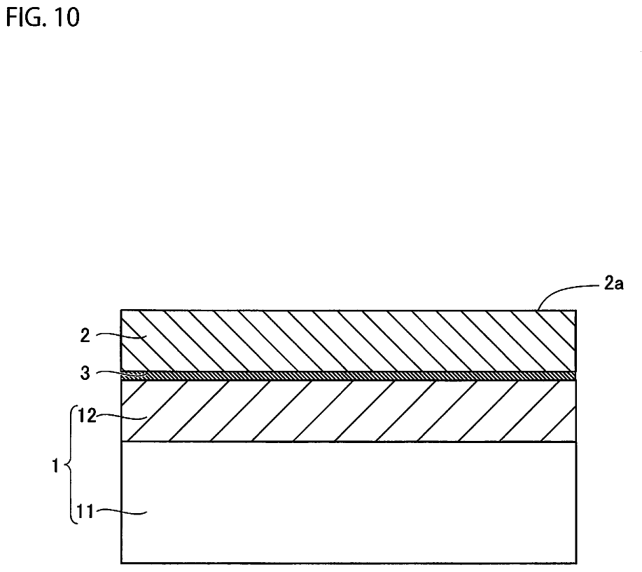

Referring to FIG. 10, the Si substrate 91 is then completely removed, for example, by mechanical polishing and wet etching. Hence, principal surface 2a of SiC layer 2 is exposed. Any method can be used to remove the Si substrate 91, such as dry etching or chemical polishing.

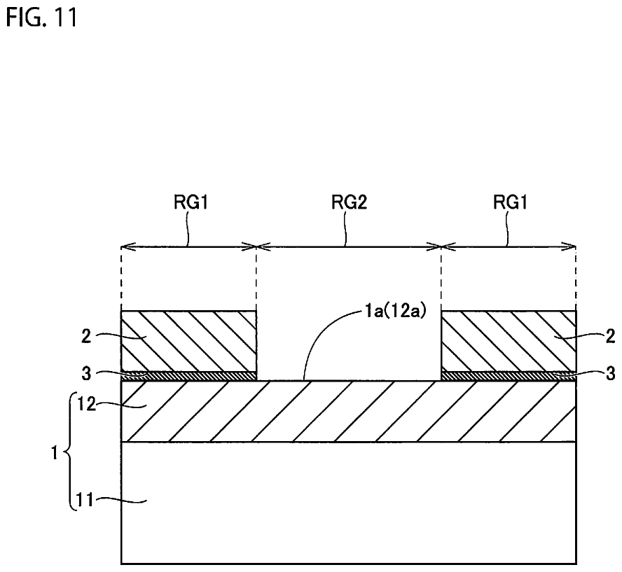

Referring to FIG. 11, next, SiC layer 2 and conjugation layer 3 present in region RG2 on principal surface 12a of drift layer 12 are removed by ordinary photolithography and dry etching techniques. Hence, region RG2 of principal surface 12a of drift layer 12 is exposed. SiC layer 2 and conjugation layer 3 existing in region RG1 on principal surface 12a of drift layer 12 remain.

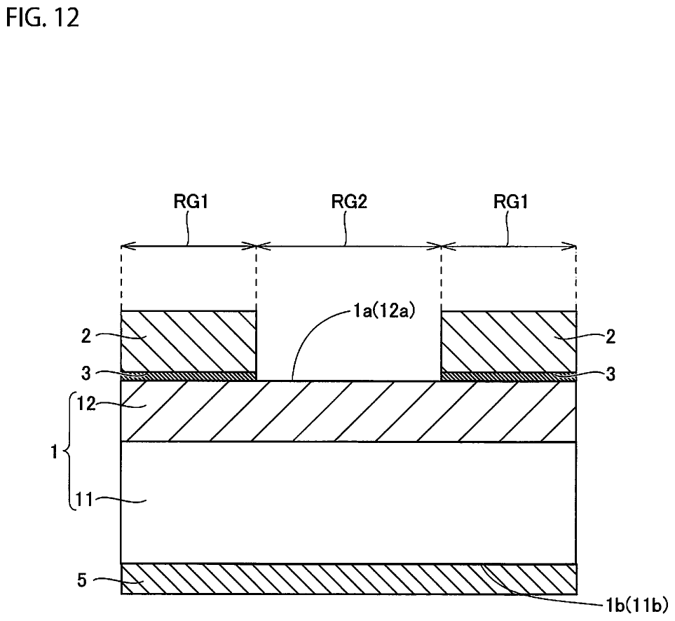

Referring to FIG. 12, next, an ohmic electrode 5 is formed on the principal surface 1b of the Ga₂O₃ substrate 1 using a method such as a deposition method.

Referring to FIG. 1, Schottky electrode 4 is then formed in region RG2 on principal surface 12a of drift layer 12 using a method such as a deposition method. Through the above steps, semiconductor element SD1 is obtained.

Note that, from the viewpoint of lowering parasitic resistance, it is preferable that the foundation substrate 11 in the semiconductor element SD1 is as thin as possible. For this reason, after bonding Ga₂O₃ substrate 1 and SiC layer 2 and before forming ohmic electrode 5, foundation substrate 11 is preferably thinned to a thickness of 5 micrometers or more and 100 micrometers or less by grinding or the like.

Next, the effects of the first embodiment will be explained.

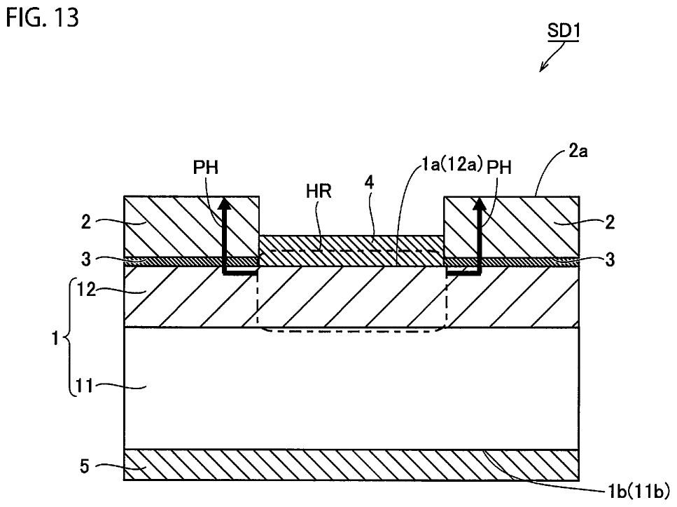

FIG. 13 is a cross-sectional view showing the heat dissipation path of semiconductor element SD1 in the first embodiment of the present invention.

Referring to FIG. 13, semiconductor element SD1 operates as follows. When a positive potential is applied to Schottky electrode 4 while ohmic electrode 5 is grounded, current flows from Schottky electrode 4 to ohmic electrode 5 via Ga₂O₃ substrate 1. Schottky electrode 4 controls the current flowing through Ga₂O₃ substrate 1. The current flowing through the Ga₂O₃ substrate 1 depends on the potential applied to the Schottky electrode 4.

When semiconductor element SD1 operates, heat is generated in region HR as the Schottky boundary face (the boundary face between principal surface 1a of Ga₂O₃ substrate 1 and Schottky electrode 4). In semiconductor element SD1, most of the heat generated in region HR travels within drift layer 12 along the extending direction of principal surface 1a of Ga₂O₃ substrate 1, is transferred to SiC layer 2, passes through the interior of SiC layer 2, and is emitted to the outside from principal surface 2a of SiC layer 2, as shown by arrow PH. In this way, according to the semiconductor element SD1, the heat generated at the Schottky boundary face is released to the side of the Ga₂O₃ substrate 1, where the Schottky electrode 4 is present (the upper side in FIG. 13). According to semiconductor element SD1, the heat radiation path can be shortened as compared with a configuration in which the heat generated at the Schottky boundary face is released from the side of Ga₂O₃ substrate 1 opposite to the side where Schottky electrode 4 is present (bottom side in FIG. 13). As a result, heat dissipation can be improved.

As a method for forming the SiC layer 2 on the principal surface 1a of Ga₂O₃ substrate 1, in addition to the above-mentioned bonding, a sputtering method, a CVD method, etc. can be adopted. However, by using bonding as a method of forming SiC layer 2 on principal surface 1a of Ga₂O₃ substrate 1, the following effects can be obtained compared to a sputtering method or a CVD method.

Firstly, by using bonding, heating of the Ga₂O₃ substrate 1 is not required when forming the SiC layer 2 on the principal surface 1a of the Ga₂O₃ substrate 1. Hence, it is possible to avoid a situation where Ga₂O₃ substrate 1 etc. are damaged due to heating. On the other hand, when using a sputtering method or CVD method, it is necessary to heat Ga₂O₃ substrate 1.

Secondly, by using bonding, a foundation layer (here, Si substrate 91) suitable for film forming of SiC layer 2 can be used when forming a film of SiC layer 2. As a result, the quality of SiC layer 2 can be improved, and single-crystal SiC layer 2 can be formed. On the other hand, when using a sputtering method or a CVD method, it is necessary to use Ga₂O₃ substrate 1 as a foundation layer. When film-forming a SiC layer using Ga₂O₃ substrate 1 as the foundation layer, the SiC layer becomes polycrystal or amorphous, and a single-crystal SiC layer cannot be obtained.

Thirdly, when bonding is used, as described above, SiC layer 2 is single crystal. A single-crystal SiC layer has higher thermal conductivity and resistivity than a polycrystal or amorphous SiC layer. For this reason, according to SiC layer 2 of single crystal, the heat dissipation of semiconductor element SD1 can be improved, and leakage current at the boundary face between Ga₂O₃ substrate 1 and SiC layer 2 can be suppressed.

### Modification of the Manufacturing Method in the First Embodiment

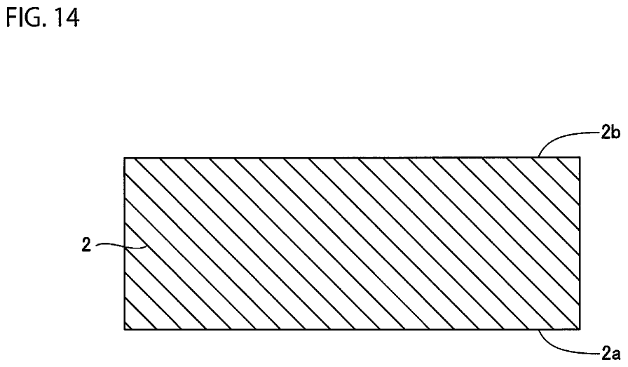

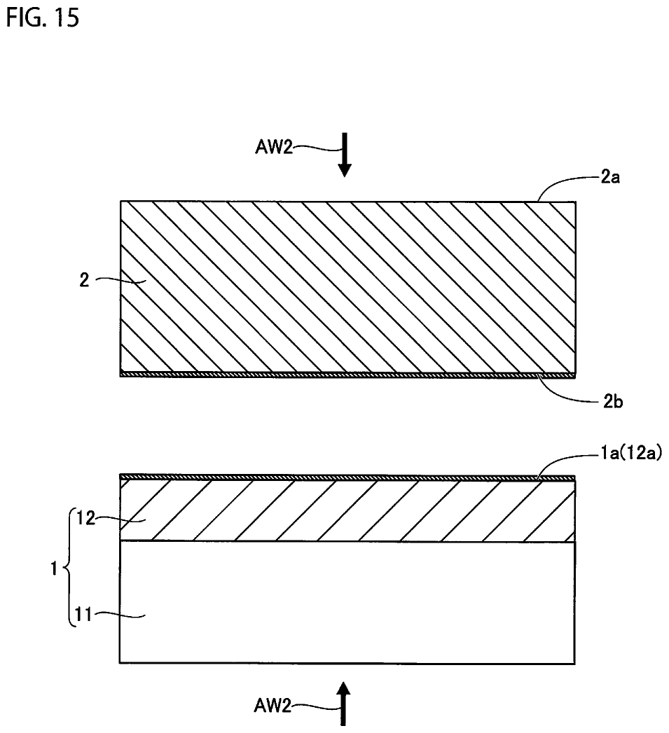

Instead of using SiC layer 2 formed on principal surface 91a of Si substrate 91 as shown in FIG. 3, a bulk SiC substrate may be used. A modification using a bulk SiC substrate as SiC layer 2 in the first embodiment will be explained using FIG. 14 and FIG. 15.

Referring to FIG. 14, SiC layer 2, which is a bulk SiC substrate is prepared. The bulk SiC substrate is produced using, for example, a sublimation method. SiC layer 2 includes two principal surfaces 2a and 2b. Principal surface 2a of SiC layer 2 faces downward in FIG. 14, and principal surface 2b of SiC layer 2 faces upward in FIG. 14. SiC layer 2 has a thickness of, for example, 100 micrometers to 500 micrometers. Note that SiC layer 2 may have n-type or p-type conductivity, or may be semi-insulating. Preferably, SiC layer 2 is not intentionally doped with impurity.

When SiC layer 2 consists of a bulk SiC substrate made using a sublimation method etc., SiC layer 2 has a crystal structure of a hexagonal crystal. When the SiC layer 2 has a hexagonal crystal structure, the plane orientation of the principal surface (a principal surface of Ga₂O₃ substrate 1 side) 2b of the SiC layer 2 is preferably (0001). The off angle of principal surface 2b of SiC layer 2 is preferably 0 degree or more and 10 degrees or less. Further, SiC layer 2 preferably satisfies at least one of the two conditions (a) and (b), where (a) The half width of the X-ray rocking curve of the plane orientation of principal surface 2b of SiC layer 2 is greater than 0 and equal to or less than 2000 arcsec, (b) The full width at half maximum of the misorientation distribution of principal surface 2b of SiC layer 2 by electron beam backscatter diffraction method is greater than 0 and equal to or less than 2000 arcsec. Hence, principal surface 2b of SiC layer 2 is a suitable surface for bonding.

Referring to FIG. 15, next, SiC layer 2 is inverted so that principal surface 2b of SiC layer 2 faces downward in FIG. 15. Ga₂O₃ substrate 1 obtained in the step shown in FIG. 2 is brought into a state with principal surface 1a facing upward in FIG. 15. In this state, as shown by arrows AW2, principal surface 1a of Ga₂O₃ substrate 1 (principal surface 12a of drift layer 12) and principal surface 2b of SiC layer 2 are bonded by any bonding method. Principal surface 2a of SiC layer 2 may be bonded to principal surface 1a of Ga₂O₃ substrate 1 (principal surface 12a of drift layer 12) instead of principal surface 2b of SiC layer 2 without inverting SiC layer 2.

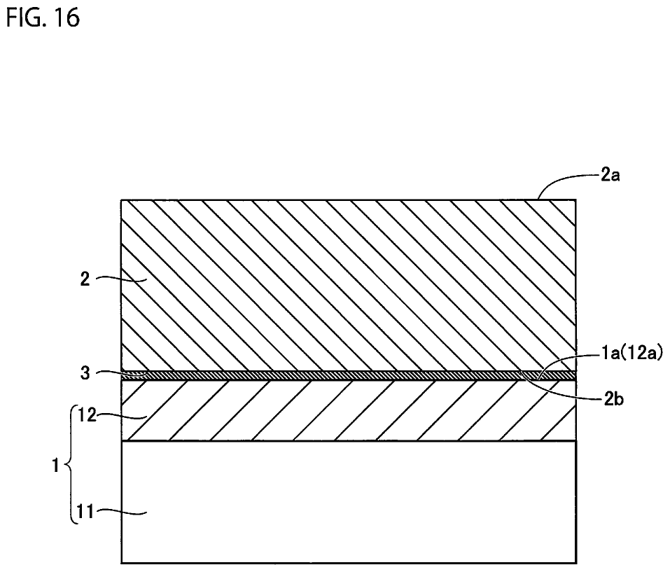

Referring to FIG. 16, after bonding, conjugation layer 3 appears between principal surface 1a of Ga₂O₃ substrate 1 and principal surface 2b of SiC layer 2. Next, SiC layer 2 is polished from the principal surface 2a side of SiC layer 2 (the principal surface opposite to the side where Ga₂O₃ substrate 1 is present) to thin SiC layer 2, for example, from 1 micrometer to 4 micrometers thick. Hence, the structure shown in FIG. 10 is obtained. Any method can be used to polish the SiC layer 2, such as mechanical polishing or chemical polishing. Thereafter, the semiconductor element SD1 is obtained through the steps from FIG. 10 onward in the first embodiment.

Furthermore, since the method for manufacturing of semiconductor element SD1 in the above modification other than the above is the same as the method for manufacturing in the first embodiment, the description will not be repeated.

### Second Embodiment

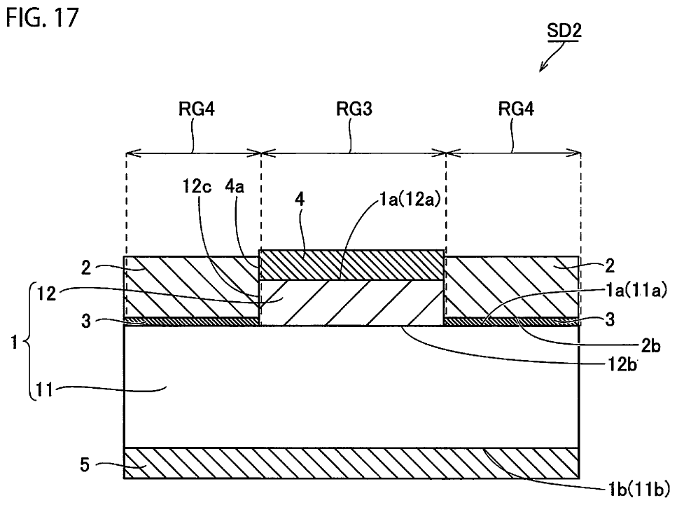

FIG. 17 is a cross-sectional view showing the configuration of semiconductor element SD2 in the second embodiment of the present invention.

Referring to FIG. 17, semiconductor element SD2 (an example of a semiconductor element) in the second embodiment is an SBD. Similar to semiconductor element SD1, semiconductor element SD2 includes Ga₂O₃ substrate 1 (an example of a gallium oxide layer), single-crystal SiC layer 2 formed at principal surface 1a side of Ga₂O₃ substrate 1 (an example of a single-crystal silicon carbide layer), and Schottky electrode 4 formed on principal surface 1a of Ga₂O₃ substrate 1 and controls the current flowing within Ga₂O₃ substrate 1. In semiconductor element SD2, Ga₂O₃ substrate 1 has a convex shape facing upward in FIG. 17 when viewed in the cross section of FIG. 17. Drift layer 12 (an example of a second gallium oxide layer) is formed in region RG3 on principal surface 11a of foundation substrate 11 (an example of a first gallium oxide layer). Principal surface 1a of Ga₂O₃ substrate 1 (the principal surface facing upward in FIG. 17) is composed of region RG4 of principal surface 11a of foundation substrate 11 and principal surface 12a of drift layer 12. Region RG4 is a different region from region RG3. In the second embodiment, region RG3 and region RG4 are adjacent to each other.

SiC layer 2 is formed at the principal surface 1a side of Ga₂O₃ substrate 1. In the second embodiment, principal surface 1a of Ga₂O₃ substrate 1 and principal surface 2b of SiC layer 2 are joined together. Side surface 12c of drift layer 12 (an example of a side surface in a second gallium oxide layer) is in contact with SiC layer 2. Side surface 12c of drift layer 12 is the plane between principal surface 12a and principal surface 12b of drift layer 12.

Conjugation layer 3 (an example of a conjugation layer) is formed at the boundary face of Ga₂O₃ substrate 1 and SiC layer 2. Conjugation layer 3 is formed in region RG4 on principal surface 11a of foundation substrate 11, and is in contact with principal surface 2b of SiC layer 2. Conjugation layer 3 is the trace of a junction between Ga₂O₃ substrate 1 and SiC layer 2.

Schottky electrode 4 (an example of a first electrode) is formed on principal surface 12a of drift layer 12. Side surface 4a of Schottky electrode 4 is in contact with SiC layer 2. Schottky electrode 4 is in Schottky contact with principal surface 1a of Ga₂O₃ substrate 1 (principal surface 12a of drift layer 12).

Note that the configuration of semiconductor element SD2 other than the above is the same as the configuration of semiconductor element SD1 in the first embodiment, so the same members are given the same numerals, and the description will not be repeated.

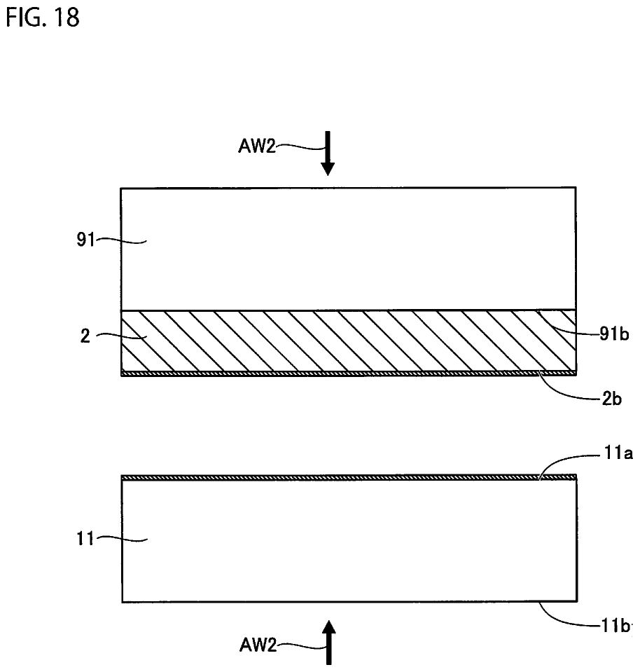

Next, a method for manufacturing of semiconductor element SD2 in the second embodiment will be explained using FIGS. 18 to 23.

Referring to FIG. 18, foundation substrate 11 is prepared, placing principal surface 11a of foundation substrate 11 facing upward in FIG. 18. SiC layer 2 and Si substrate 91 obtained by the step shown in FIG. 3 are in a state where principal surface 91b of Si substrate 91 and principal surface 2b of SiC layer 2 face downward in FIG. 18. In this state, as shown by arrows AW2, principal surface 11a of foundation substrate 11 and principal surface 2b of SiC layer 2 are bonded using any bonding method.

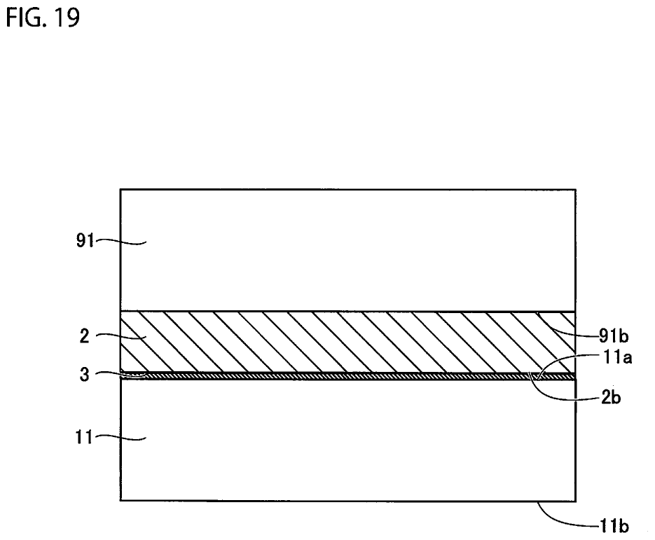

Referring to FIG. 19, after bonding, conjugation layer 3 appears between principal surface 11a of foundation substrate layer 11 and principal surface 2b of SiC layer 2.

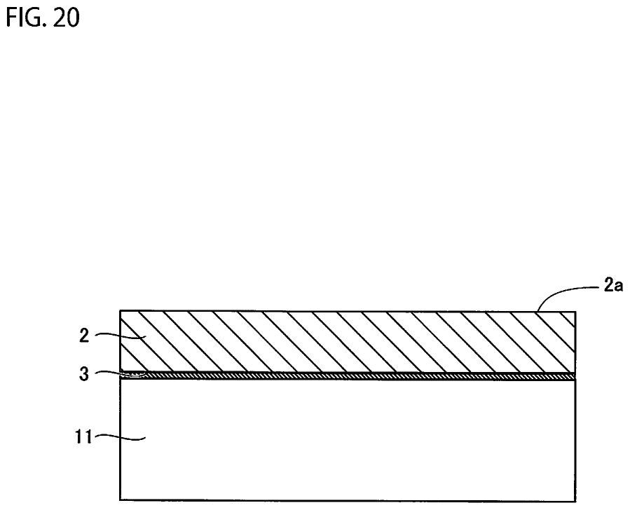

Referring to FIG. 20, next, Si substrate 91 is removed. Hence, principal surface 2a of SiC layer 2 is exposed.

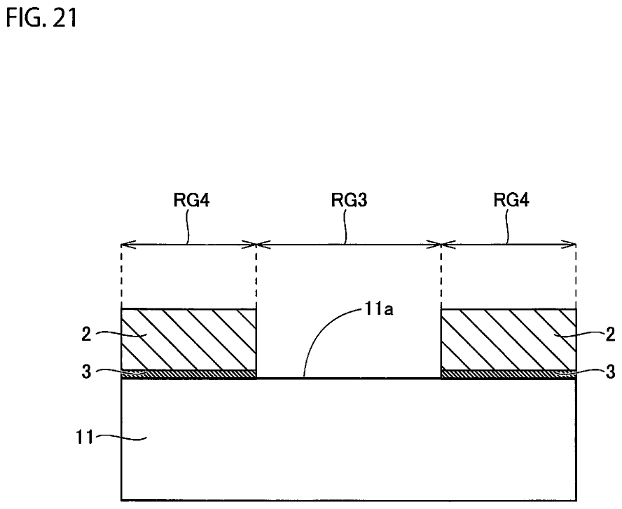

Referring to FIG. 21, next, SiC layer 2 and conjugation layer 3 present in region RG3 on principal surface 11a of foundation substrate 11 are removed by ordinary photolithography and etching techniques. Hence, principal surface 11a of foundation substrate 11 in region RG3 is exposed. SiC layer 2 and conjugation layer 3 present in region RG4 on principal surface 11a of foundation substrate 11 remain.

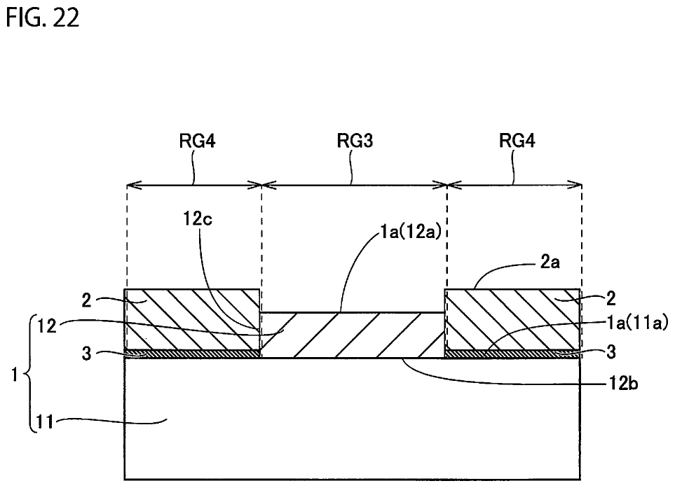

Referring to FIG. 22, next, drift layer 12 is formed in region RG3 on principal surface 11a of foundation substrate 11. After forming a Ga₂O₃ layer on principal surface 1a of foundation substrate 11 and principal surface 2a of SiC layer 2, the excess Ga₂O₃ layer present on principal surface 2a of SiC layer 2 is removed by etching. The remaining Ga₂O₃ layer becomes drift layer 12. Drift layer 12 epitaxially grows on principal surface 11a of foundation substrate 11. Principal surface 12a of drift layer 12 becomes a part of principal surface 1a of Ga₂O₃ substrate 1.

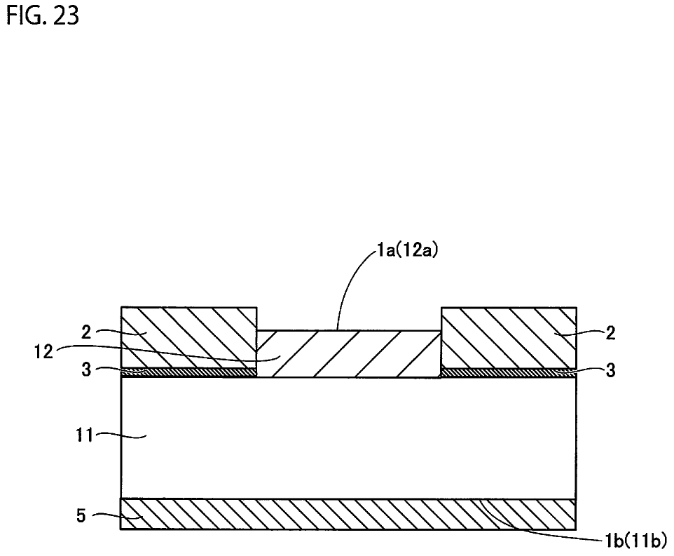

Referring to FIG. 23, next, ohmic electrode 5 is formed on principal surface 11b of foundation substrate 11.

Referring to FIG. 17, Schottky electrode 4 is then formed on principal surface 12a of drift layer 12. Through the above steps, semiconductor element SD2 is obtained.

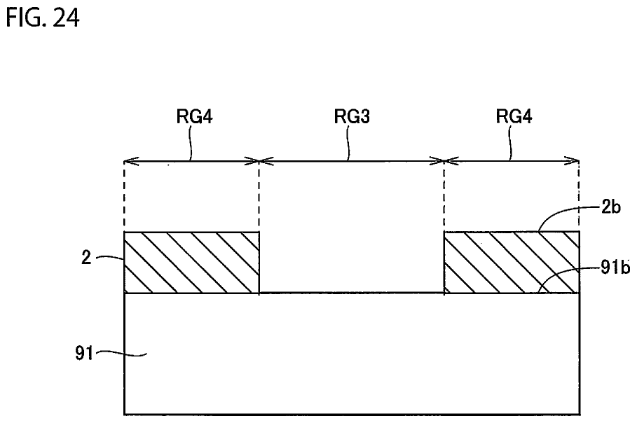

Next, a modification of the method for manufacturing of semiconductor element SD2 in the second embodiment will be explained using FIGS. 24 to 26.

Referring to FIG. 24, Si substrate 91 is prepared. Next, a single-crystal SiC layer 2 is formed on the principal surface 91b of the Si substrate 91. Next, the SiC layer 2 present in the region RG3 on the principal surface 91b of the Si substrate 91 is removed by ordinary photolithography and dry etching techniques. Hence, principal surface 91b of Si substrate 91 in region RG3 is exposed. SiC layer 2 present in region RG4 of principal surface 91b of Si substrate 91 remains.

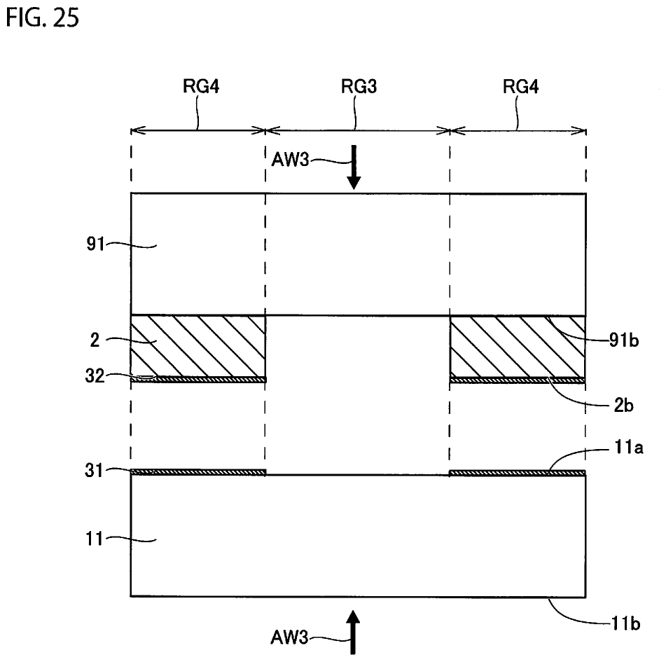

Referring to FIG. 25, next, foundation substrate 11 is prepared, with principal surface 11a of foundation substrate 11 facing upward in FIG. 25. The SiC layer 2 and Si substrate 91 obtained in the step shown in FIG. 24 are brought into a state in which the principal surface 91b of Si substrate 91 and the principal surface 2b of SiC layer 2 face downward in FIG. 25. In this state, as shown by arrows AW3, principal surface 11a of foundation substrate 11 and principal surface 2b of SiC layer 2 are bonded by any bonding method at region RG4.

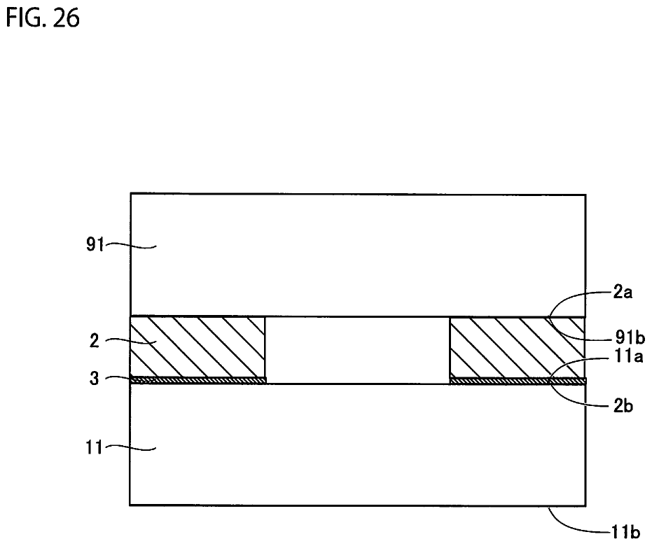

Referring to FIG. 26, after bonding, conjugation layer 3 appears between principal surface 11a of foundation substrate 11 and principal surface 2b of SiC layer 2 in region RG4. Next, the Si substrate 91 is removed. Hence, principal surface 2a of SiC layer 2 is exposed, and the structure shown in FIG. 21 is obtained.

Thereafter, through the steps shown in FIGS. 22 and 23, a drift layer 12 is formed on the principal surface 2a of the SiC layer 2. Ohmic electrode 5 is formed on principal surface 11b of foundation substrate 11. Schottky electrode 4 is formed on principal surface 12a of drift layer 12. Through the above steps, semiconductor element SD2 is obtained.

In this modification of the method for manufacturing, before bonding foundation substrate 11 and SiC layer 2, by removing a part of SiC layer 2 while Si substrate 91 is the foundation layer of SiC layer 2, principal surface 91b of Si substrate 91 in region RG3 is exposed (In other words, before bonding foundation substrate 11 and SiC layer 2, a mesa structure of SiC layer 2 is formed). Hence, damage to Ga₂O₃ substrate 1 during removal of SiC layer 2 can be suppressed.

Since the method for manufacturing (in particular, manufacturing conditions, etc.) of semiconductor element SD2 other than those mentioned above in the second embodiment and its modification is the same as the method for manufacturing in the first embodiment, the description will not be repeated.

Next, the effects of the second embodiment will be explained.

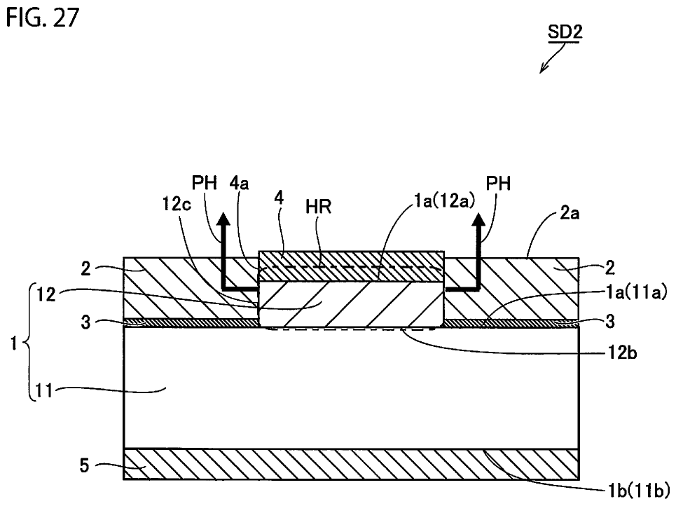

FIG. 27 is a cross-sectional view showing the heat dissipation path of semiconductor element SD2 in the second embodiment of the present invention.

Referring to FIG. 27, semiconductor element SD2 operates as follows. When a positive potential is applied to Schottky electrode 4 while ohmic electrode 5 is grounded, current flows from Schottky electrode 4 to ohmic electrode 5 via Ga₂O₃ substrate 1. Schottky electrode 4 controls the current flowing through Ga₂O₃ substrate 1. The current flowing through the Ga₂O₃ substrate 1 depends on the potential applied to the Schottky electrode 4.

When semiconductor element SD2 operates, heat is generated in region HR, which is the Schottky boundary face (the boundary face between principal surface 1a of Ga₂O₃ substrate 1 and Schottky electrode 4). According to the second embodiment, effects similar to those of the first embodiment can be obtained.

In semiconductor element SD2, most of the heat generated in region HR is transmitted from drift layer 12 to SiC layer 2 along the extending direction of principal surface 1a of Ga₂O₃ substrate 1, passes through the inside of SiC layer 2, and is emitted from principal surface 2a of SiC layer 2 to the outside, as shown by the arrows PH. In this way, according to semiconductor element SD2, the heat generated in Schottky boundary face is released to the side of Ga₂O₃ substrate 1 where Schottky electrode 4 is present (upper side in FIG. 27). According to semiconductor element SD2, the heat dissipation path can be made shorter compared to a configuration in which the heat generated by Schottky boundary face is released from the side of Ga₂O₃ substrate 1 opposite to the side where Schottky electrode 4 is present (lower side in FIG. 27). As a result, heat dissipation can be improved.

In the second embodiment, a high temperature heat treatment process is required when forming each of drift layer 12 and ohmic electrode 5. According to the second embodiment, for the joint interface of foundation substrate 11 and SiC layer 2, it is possible to obtain thermal resistance at 1000 degrees Celsius, which is higher than the temperature expected in these heat treatment processes.

### Third Embodiment

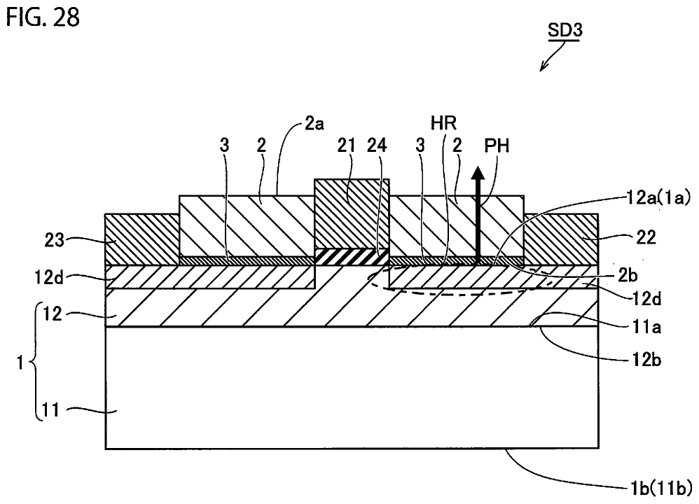

FIG. 28 is a cross-sectional view showing the configuration of semiconductor element SD3 in the third embodiment of the present invention.

Referring to FIG. 28, semiconductor element SD3 (an example of semiconductor element) in the third embodiment is a horizontal MOSFET (Metal-Oxide-Semiconductor Field Effect Transistor). Similar to semiconductor element SD1, semiconductor element SD3 includes Ga₂O₃ substrate 1 (an example of a gallium oxide layer), single-crystal SiC layer 2 formed at principal surface 1a side of Ga₂O₃ substrate 1 (an example of a single-crystal silicon carbide), and gate electrode 21 formed at the principal surface 1a side of Ga₂O₃ substrate 1 and controlling the current flowing in Ga₂O₃ substrate 1 (an example of a first electrode). In particular, semiconductor element SD3 includes Ga₂O₃ substrate 1, SiC layer 2, conjugation layer 3, gate electrode 21, drain electrode 22, source electrode 23, and gate insulation film 24. Ga₂O₃ substrate 1 contains two principal surfaces 1a and 1b. Principal surface 1a of Ga₂O₃ substrate 1 is facing upward in FIG. 28. Principal surface 1b of Ga₂O₃ substrate 1 faces downward in FIG. 28. It is preferable that the thickness of Ga₂O₃ substrate 1 is adjusted according to the withstand voltage required for semiconductor element SD3. Ga₂O₃ substrate 1 includes foundation substrate 11 (an example of a first gallium oxide layer) and Ga₂O₃ layer 12 (an example of a side surface of a second gallium oxide layer). In semiconductor element SD3, Ga₂O₃ layer 12 does not strictly have the function of a drift layer, so according to this embodiment, it is written as a “Ga₂O₃ layer” instead of a “drift layer”. Foundation substrate 11 contains two principal surfaces 11a and 11b. Principal surface 11a of foundation substrate 11 is facing upward in FIG. 28. Principal surface 11b of foundation substrate 11 faces downward in FIG. 28, and constitutes principal surface 1b of Ga₂O₃ substrate 1. Foundation substrate 11 only needs to have impurity concentration according to the design of semiconductor element SD3, and may be semi-insulating, or may be metalized by increasing the impurity concentration.

Ga₂O₃ layer 12 is formed on principal surface 11a of foundation substrate 11. Ga₂O₃ layer 12 includes two principal surfaces 12a and 12b. Principal surface 12a of Ga₂O₃ layer 12 faces upward in FIG. 28 and constitutes principal surface 1a of Ga₂O₃ substrate 1. Principal surface 12b of Ga₂O₃ layer 12 faces downward in FIG. 28 and is in contact with principal surface 11a of foundation substrate 11. The conductivity of Ga₂O₃ layer12 is higher than that of foundation substrate11. For conductivity adjustment, Ga₂O₃ layer 12 contains impurity, for example N introduced by an ion implantation, and has p-type conductivity or semi-insulating. Ga₂O₃ layer 12 may have a conductivity of n-type which is higher in resistance than n-type region 12d. In this case, semiconductor element SD3 is a Normally-on MOSFET. Preferably, Ga₂O₃ layer 12 has a thickness of 1 micrometer or more and 50 micrometers or less. The thickness of Ga₂O₃ layer 12 is set according to the withstand voltage required of the MOSFET.

Ga₂O₃ layer 12 contains two n-type regions 12d. Each of the two n-type regions 12d is formed to face principal surface 12a of Ga₂O₃ layer 12. Each of the two n-type regions 12d contains impurity such as Si, Sn, or Ge and has a conductivity of n-type.

The area near principal surface 1a of Ga₂O₃ substrate 1 between gate electrode 21 and drain electrode 22 is defined as region HR. Region HR in Ga₂O₃ layer 12 preferably has an impurity concentration of 10¹⁴ to 10⁴⁷/cm³, regardless of the conductivity type. The impurity concentration of the region HR in Ga₂O₃ layer 12 is set according to the withstand voltage required for semiconductor element SD3. On the other hand, from the perspective of reducing MOSFET parasitic resistance, it is preferable that the impurity concentration in the region other than the region HR in Ga₂O₃ layer 12 (i.e. the n-type region on the right side of region HR and the n-type region on the left side of semiconductor element SD3) has as high impurity concentration as possible, and it preferably have a impurity concentration of 10¹⁸/cm³ or more and 10²⁰/cm³ or less.

Each of drain electrode 22 and source electrode 23 is formed on principal surface 1a of Ga₂O₃ substrate 1. Drain electrode 22 and source electrode 23 are each in contact with each of the two n-type regions 12d.

Gate electrode 21 is formed on principal surface 1a of Ga₂O₃ substrate 1 via gate insulation film 24. Gate electrode 21 is provided between drain electrode 22 and source electrode 23.

SiC layer 2 is formed at the principal surface 1a side of Ga₂O₃ substrate 1. SiC layer 2 is a single-crystal and has a crystal structure such as 3C type, hexagonal crystal, or the like. SiC layer 2 contains two principal surfaces 2a and 2b. Principal surface 2a of SiC layer 2 faces upward in FIG. 28, and principal surface 2b of SiC layer 2 faces downward in FIG. 28. SiC layer 2 has a thickness of, for example, 1 micrometer to 4 micrometers. In the third embodiment, principal surface 1a of Ga₂O₃ substrate 1 and principal surface 2b of SiC layer 2 are joined together. SiC layer 2 of single-crystal has high thermal conductivity. For this reason, SiC layer 2 plays a role of discharging the heat generated in semiconductor element SD3 to the outside.

Conjugation layer 3 is formed at the boundary face between each of the two n-type regions 12d of Ga₂O₃ substrate 1 and SiC layer 2. Conjugation layer 3 is formed on principal surface 1a of Ga₂O₃ substrate 1. Conjugation layer 3 is formed between gate electrode 21 and drain electrode 22 and between gate electrode 21 and source electrode 23. Conjugation layer 3 is in contact with principal surface 2b of SiC layer 2. Conjugation layer 3 is the trace of a junction between Ga₂O₃ substrate 1 and SiC layer 2. If Ga₂O₃ substrate 1 and SiC layer 2 are not joined, conjugation layer 3 will not appear.

Semiconductor element SD3 is produced in substantially the same manner as semiconductor element SD1 in the first embodiment. When joining Ga₂O₃ substrate 1 and SiC layer 2, foundation substrate 11 needs to play a role of a supporting member. For this reason, before joining Ga₂O₃ substrate 1 and SiC layer 2, foundation substrate 11 preferably has a thickness of 100 micrometers or more and 1000 micrometers or less. On the other hand, after joining Ga₂O₃ substrate 1 and SiC layer 2 but before forming ohmic electrode 5, from the viewpoint of improving heat dissipation from the lower part of foundation substrate 11, foundation substrate 11 is preferably thinned to a thickness of 5 micrometers or more and 100 micrometers or less by grinding or the like.

Note that the configuration of semiconductor element SD3 other than the above and the method for manufacturing are almost the same as the configuration of semiconductor element SD1 in the first embodiment, the same members are given the same numerals, the description will not be repeated.

Semiconductor element SD3 operates as follows. Source electrode 23 is always held at ground potential. In this state, when a positive voltage is applied to each of gate electrode 21 and drain electrode 22, a channel is formed at principal surface 1a of Ga₂O₃ substrate 1 directly below gate electrode 21, and current flows from drain electrode 22 to source electrode 23 through each of the two n-type regions 121. The magnitude of this current is controlled by the voltage applied to gate electrode 21. In other words, gate electrode 21 controls the current flowing within Ga₂O₃ substrate 1.

When the semiconductor element SD3 operates, heat is generated in the region HR near principal surface 1a of Ga₂O₃ substrate 1 between gate electrode 21 and drain electrode 22. According to the third embodiment, effects similar to those of the first embodiment can be obtained.

In semiconductor element SD3, most of the heat generated in region HR is transmitted from Ga₂O₃ layer 12 to SiC layer 2 along the normal direction of principal surface 1a of Ga₂O₃ substrate 1, and passes through SiC layer 2, and released from principal surface 2a of SiC layer 2 to the outside, as shown by the arrow PH. In this way, according to semiconductor element SD3, the heat generated in semiconductor element SD3 is released to the side of Ga₂O₃ substrate 1 where gate electrode 21 is present (upper side in FIG. 28). According to semiconductor element SD3, the heat radiation path can be made shorter, as compared to a configuration in which heat generated in semiconductor element SD3 is released from the side of Ga₂O₃ substrate 1 opposite to the side where gate electrode 21 is present (lower side in FIG. 28). As a result, heat dissipation can be improved.

### EXAMPLES

As the first Example, the inventors of the present application manufactured each of Samples 1 to 3 having the configuration described below as samples. The thermal resistance values of each of the obtained Samples 1 to 3 were calculated.

Samples 1 (an example of the present invention): Five samples having a structure similar to semiconductor element SD1 shown in FIG. 1 were manufactured. The thickness of the drift layer of each of the five samples that form Samples 1 was set to 10 micrometers, 20 micrometers, 30 micrometers, 40 micrometers, and 50 micrometers, respectively.

Samples 2 (an example of the present invention): Five samples having a structure similar to semiconductor element SD2 shown in FIG. 17 were manufactured. The thickness of the drift layer of each of the five samples that forms Samples 2 was set to 10 micrometers, 20 micrometers, 30 micrometers, 40 micrometers, and 50 micrometers, respectively.

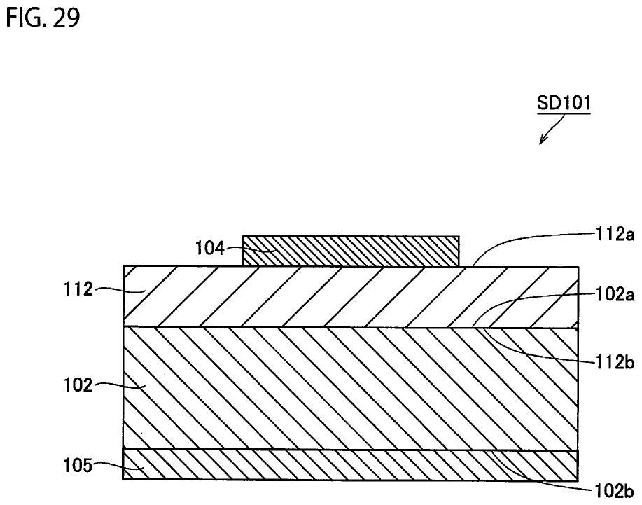

Samples 3 (a comparative example): Five samples having a structure similar to semiconductor element SD101 shown in FIG. 29 were manufactured. The thickness of the drift layer of each of the five samples that forms Samples 3 is 10 micrometers, 20 micrometers, 30 micrometers, 40 micrometers, and 50 micrometers, respectively.

Referring to FIG. 29, semiconductor element SD101 includes Ga₂O₃ drift layer 112, SiC substrate 102, Schottky electrode 104, and ohmic electrode 105. Ga₂O₃ drift layer 112 includes principal surfaces 112a and 112b. Principal surface 112a faces upward in FIG. 29, and principal surface 112b faces downward in FIG. 29. Schottky electrode 104 is formed on a part of principal surface 112a of Ga₂O₃ drift layer 112.

SiC substrate 102 is formed on principal surface 112b of Ga₂O₃ drift layer 112. The SiC substrate 102 is provided on the principal surface 112b of the Ga₂O₃ drift layer 112 on the side opposite to the side where the Schottky electrode 104 is present (lower side in FIG. 29). The SiC substrate is polycrystal. SiC substrate 102 includes principal surfaces 102a and 102b. Principal surface 102a faces upward in FIG. 29, and principal surface 102b faces downward in FIG. 29. Principal surface 102a of SiC substrate 102 is joined to principal surface 112b of Ga₂O₃ drift layer 112. Ohmic electrode 105 is formed on the principal surface 102b of the SiC substrate 102.

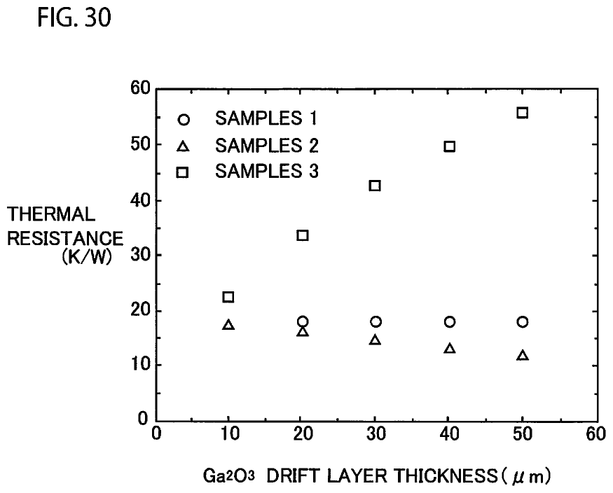

FIG. 30 is a diagram showing the relationship between the thermal resistance value and the thickness of the drift layer of each of Samples 1 to 3 in the first Example of the present invention.

Referring to FIG. 30, when the thickness of the drift layer is 10 micrometers, the thermal resistance value was reduced by about 25% in each of Samples 1 and 2, as compared to Sample 3. As the thickness of the drift layer increases, the reduction ratio of the thermal resistance values of Samples 1 and 2 relative to Sample 3 increases. These results are presumed to be due to the following reasons. In Samples 3, the heat generated during operation is transmitted through the drift layer in the thickness direction and is radiated to the ohmic electrode side through the SiC layer. On the other hand, in Samples 1 and 2, the heat generated during operation is not transmitted through the drift layer in the thickness direction, but is radiated to the Schottky electrode side through the SiC layer. For this reason, each of the heat radiation paths of Samples 1 and 2 is shorter, compared to the heat radiation path of Samples 3.

In Samples 3, the thermal resistance value increased significantly as the thickness of the drift layer increased, whereas in Samples 1, the thermal resistance value remained almost constant even when the thickness of the drift layer increased. In samples 2, the thermal resistance value decreased as the thickness of the drift layer increased. It is presumed that the result that the thermal resistance value of Samples 2 decreased as the thickness of drift layer increased was due to the increase in the contact area between the side surface of the drift layer and the SiC layer as the thickness of drift layer increased.

As the second Examples, the inventors of the present application manufactured Samples 4 having the configuration described below as samples. The surface temperature (the maximum temperature of the Schottky electrode) during operation of each of the obtained Samples 4 was investigated.

Samples 4: Six samples having basically the same structure as semiconductor element SD2 shown in FIG. 17 were manufactured. However, one sample out of the six samples that make up Samples 4 is a comparative example, and the thickness of SiC layer is set to 0 (in other words, a SiC layer was not formed). The remaining 5 samples out of the 6 samples in Samples 4 were as examples of the present invention, and the thickness of the SiC layer was set as 10 micrometers, 20 micrometers, 30 micrometers, 40 micrometers, and 50 micrometers, respectively. For all samples, the drift layer diameter was 30 micrometers, the drift layer thickness was 10 micrometers, and the SiC layer diameter was 100 micrometers.

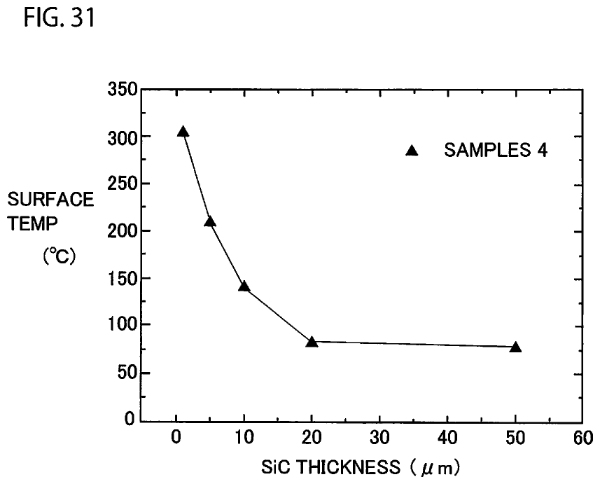

FIG. 31 is a diagram showing the relationship between the surface temperature and the thickness of SiC layer of Samples 4 in the second example of the present invention.

Referring to FIG. 31, by forming the SiC layer, the surface temperature was significantly reduced. In particular, when the thickness of the SiC layer was set to 20 micrometers or more, the surface temperature is less than or equal to 100 degrees Celsius. It can be seen that by setting the thickness of the SiC layer to 20 micrometers or more, which is twice the thickness of the drift layer, the increase in the surface temperature can be effectively suppressed.

As the third Example, the inventors of the present application manufactured Sample 5 having the configuration described below as samples. Using the thermo-reflectance signal of Sample 5, the thermal resistance of the boundary face between the SiC layer and the Ga₂O₃ substrate was calculated.

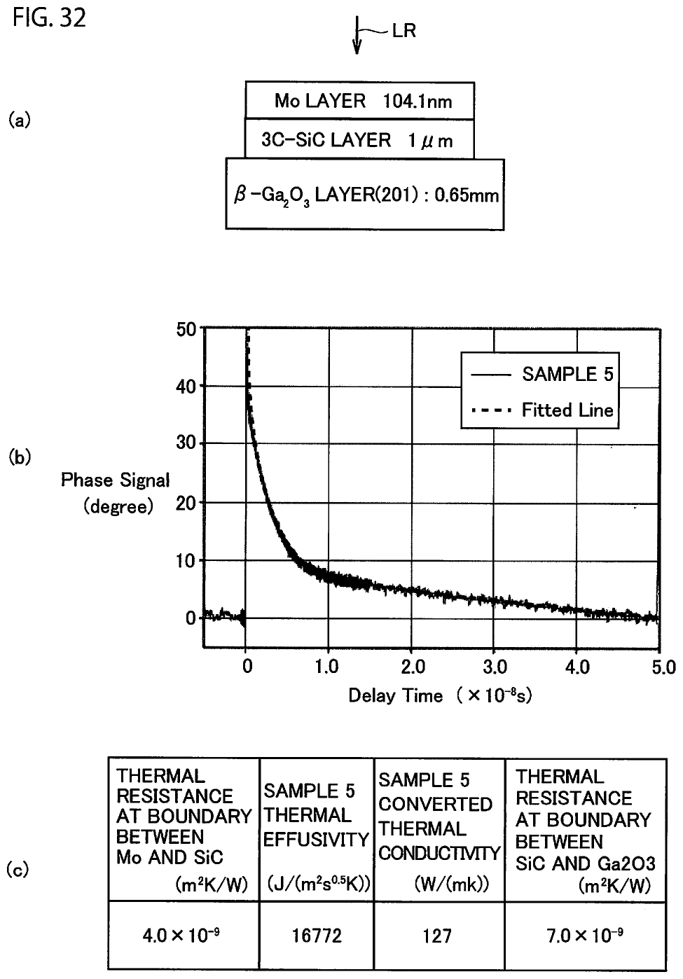

FIG. 32 is a diagram showing the configuration of Sample 5 and each measurement value of Sample 5 in the third Example of the present invention.

Referring to FIG. 32(a), a 3C type SiC layer was bonded to the (201) plane of R type Ga₂O₃ substrate using a surface activated bonding method. Next, using a deposition method or sputtering method, a Mo (molybdenum) layer was formed on the principal surface of the SiC layer opposite to the principal surface to which the Ga₂O₃ substrate was bonded. The Ga₂O₃ substrate had a thickness of 0.65 millimeter. The SiC layer had a thickness of 1 micrometer. The Mo layer had a thickness of 104.1 nanometers.

Next, referring to FIG. 32(b), the thermo-reflectance signals of Sample 5 were measured by the time domain thermo-reflectance method. In particular, the principal surface of the Mo layer opposite to the principal surface to which the SiC layer was bonded was irradiated with heating light consisting of periodically modulated laser light and detection light consisting of continuous wave laser light. The heating light and the detection light were each irradiated as shown by the arrow LR, and were irradiated so that they were on the same axis. The reflected light of the detection light was received and thermos-reflectance signals were obtained.

Referring to FIG. 32(c), the thermal effusivity of Sample 5 was measured based on the obtained thermo-reflectance signal. Next, the thermal effusivity of Sample 5 was converted to the thermal conductivity of Sample 5. Next, using known values such as the thermal resistance of the boundary face between the Mo layer and the SiC layer, the thermal resistance of the boundary face between the SiC layer and the Ga₂O₃ substrate was calculated from the obtained thermal conductivity of Sample 5. As a result, the thermal resistance of the boundary face between the SiC layer and the Ga₂O₃ substrate was found to be 7.0*10⁻⁹ (m²K/W), which is extremely low.

As explained above, the present invention provides a semiconductor element and a method for manufacturing a semiconductor element that can improve heat dissipation. According to the present invention, it is possible to obtain an energy saving effect by improving the power energy conversion efficiency of the semiconductor element, thereby contributing to the achievement of sustainable development goals.

### Others

The semiconductor element of the present invention may be other than the SBD and the horizontal MOSFET.

The configurations and manufacturing methods in above embodiments, modifications and examples can be combined as appropriate. For example, for semiconductor element SD2 of the second embodiment and semiconductor element SD3 of the third embodiment, a bulk SiC substrate may be used as SiC layer 2, and hydrophilic bonding may be used as the bonding method. Further, as the method for manufacturing of semiconductor element SD1 in the first embodiment, the same method as the modification of the method for manufacturing of the second embodiment may be used. That is, before joining Ga₂O₃ substrate 1 and SiC layer 2, by removing a part of SiC layer 2 while Si substrate 91 is a foundation layer of SiC layer 2, principal surface 91b of Si substrate 91 may be exposed.

The above-described embodiments, modifications, and examples should be considered illustrative in all respects and not restrictive. The scope of the present invention is shown not by the above description but by the scope of the claims, and is intended to include meanings equivalent to the scope of the claims and all modification s within the scope.

### EXPLANATION OF SYMBOLS

1 Ga₂O₃ (gallium oxide) substrate (an example of a gallium oxide layer)
1a, 1b principal surface of a Ga₂O₃ substrate
2 SiC (silicon carbide) layer (an example of a single-crystal silicon carbide layer)
2a, 2b principal surface of SiC layer 3 conjugation layer (an example of a conjugation layer)
4, 104 Schottky electrode (an example of a first electrode)
4a side surface of the Schottky electrode
5, 105 ohmic electrode (an example of a second electrode)
11 foundation substrate of the Ga₂O₃ substrate (an example of a first gallium oxide layer)
11a, 11b principal surface of the foundation substrate
12 drift layer or Ga₂O₃ layer of the Ga₂O₃ substrate (an example of a second gallium oxide layer)
12a, 12b principal surface of the drift layer
12c side surface of the drift layer (an example of a side surface of a second gallium oxide layer)
12d n-type region in the drift layer
21 gate electrode (an example of a first electrode)
22 drain electrode
23 source electrode
24 gate insulation film
31, 32 amorphous layer (an example of first and second amorphous layers)
33, 34 SiO₂ (silicon oxide) layer
91 Si (silicon) substrate
91a, 91b principal surface of the Si substrate
102 SiC substrate
102a, 102b principal surface of the SiC substrate
112 Ga₂O₃ drift layer
112a, 112b principal surface of Ga₂O₃ drift layer
HR area where heat is generated
RG1, RG2 region of the principal surface of the drift layer
RG3, RG4 region of the principal surface of the foundation substrate
SD1, SD2, SD3, SD101 semiconductor element (an example of a semiconductor element)

What is claimed is:

1. A semiconductor element comprising:
a gallium oxide layer;
a single-crystal silicon carbide layer formed at one principal surface side of the gallium oxide layer; and
a first electrode formed at the one principal surface side of the gallium oxide layer and controls current flowing inside the gallium oxide layer.

2. The semiconductor element according to claim 1, wherein
the silicon carbide layer has a 3C type crystal structure,
a plane orientation of a principal surface of the silicon carbide layer at the gallium oxide layer side is (111), (100), or (110),
an off angle of the principal surface of the silicon carbide layer at the gallium oxide layer side is between 0° and 10°, and
the silicon carbide layer satisfies at least one of the conditions of a half width of a X-ray rocking curve of the surface orientation of the principal surface of the silicon carbide layer at the gallium oxide layer side is greater than 0 and equal to or less than 2000 arcsec, and a full width at half maximum of the misorientation distribution of the principal surface of the silicon carbide layer at the gallium oxide layer side determined by an electron beam backscatter diffraction method is greater than 0 and equal to or less than 2000 arcsec.

3. The semiconductor element according to claim 1, wherein
the silicon carbide layer has a crystal structure of a hexagonal crystal,
the surface orientation of the principal surface of the silicon carbide layer at the gallium oxide layer side is (0001),
an off angle of the principal surface of the silicon carbide layer at the gallium oxide layer side is between 0° and 10°, and
the silicon carbide layer satisfies at least one of the conditions of a half width of a X-ray rocking curve of the surface orientation of the principal surface of the silicon carbide layer at the gallium oxide layer side is greater than 0 and equal to or less than 2000 arcsec, and a full width at half maximum of the misorientation distribution of the principal surface of the silicon carbide layer at the gallium oxide layer side determined by an electron beam backscatter diffraction method is greater than 0 and equal to or less than 2000 arcsec.

4. The semiconductor element according to claim 1, further comprising:
a conjugation layer formed at a boundary face between the gallium oxide layer and the silicon carbide layer.

5. The semiconductor element according to claim 4, wherein
the conjugation layer includes
a first amorphous layer consisting of gallium oxide formed on the one principal surface of the gallium oxide layer, and
a second amorphous layer consisting of silicon carbide formed between the first amorphous layer and the silicon carbide layer.

6. The semiconductor element according to claim 4, wherein
the conjugation layer includes silicon oxide.

7. The semiconductor element according to claim 4, wherein
the gallium oxide layer includes
a first gallium oxide layer, and
a second gallium oxide layer formed on one principal surface of the first gallium oxide layer and having a lower conductivity than the first gallium oxide layer.

8. The semiconductor element according to claim 7, wherein
the conjugation layer is formed in a first region of one principal surface of the second gallium oxide layer, and
the first electrode is formed in a second region of the one principal surface of the second gallium oxide layer, which is different from the first region.

9. The semiconductor element according to claim 7, wherein
the second gallium oxide layer is formed in a third region of the one principal surface of the first gallium oxide layer,
the conjugation layer is formed in a fourth region of the one principal surface of the first gallium oxide layer, which is different from the third region, and
the first electrode is formed on one principal surface of the second gallium oxide layer.

10. The semiconductor element according to claim 9, wherein
a side surface, which is a surface between two principal surfaces of the second gallium oxide layer, contacts the silicon carbide layer.

11. The semiconductor element according to claim 1, wherein
the first electrode is in Schottky contact with the gallium oxide layer, and the semiconductor element further comprising:
a second electrode in ohmic contact with other principal surface of the gallium oxide layer.

12. A method for manufacturing a semiconductor element comprising:
a step of joining one principal surface of a gallium oxide layer and a single-crystal silicon carbide layer; and
a step of forming a first electrode at the one principal surface side of the gallium oxide layer for controlling current flowing in the gallium oxide layer.
